(19) United States
(12) Patent Application Publication
(10) Pub. No.: US 2024/0059056 A1
(43) Pub. Date: Feb. 22, 2024

(54) COVER WINDOW OF SUBSTRATE-LESS TYPE FOR DISPLAY DEVICE, DISPLAY DEVICE INCLUDING THE SAME AND METHOD FOR MANUFACTURING THEREOF

(71) Applicant: LG CHEM, LTD., Seoul (KR)

(72) Inventors: Eun Seon LEE, Daejeon (KR); Seung Joon LIM, Daejeon (KR); Yoon Bin LIM, Daejeon (KR); Seungil BAEK, Daejeon (KR); Myoungseok CHO, Daejeon (KR); Yeongkyu CHOI, Daejeon (KR); Gieun PARK, Daejeon (KR)

(73) Assignee: LG CHEM, LTD., Seoul (KR)

(21) Appl. No.: 18/259,034

(22) PCT Filed: Oct. 7, 2022
(86) PCT No.: PCT/KR2022/015179

§ 371 Date: Jun. 22, 2023

(30) Foreign Application Priority Data
Oct. 8, 2021 (KR) 10-2021-0134122

(51) Int. Cl. B32B 27/28; B32B 7/12; B32B 37/12; B32B 27/18; B32B 17/10; H05K 5/03

(52) U.S. Cl. CPC B32B 27/283; B32B 7/12; B32B 37/12; B32B 27/18; B32B 17/10; H05K 5/03; B32B 2457/20; B32B 2307/7376; B32B 2383/00

(57) ABSTRACT

The present invention relates to a cover window for a flexible display device of substrate-less type which simultaneously achieves a physical property balance between flexibility and high hardness even without a substrate film, particularly has almost no damage to the film even by repetitive bending or folding operation, and thus, can be easily applied to bendable, flexible, rollable, or foldable mobile devices, display devices, and the like, and a flexible display device including the same.

### CROSS-REFERENCE TO RELATED APPLICATION(S)

This application is a 35 U.S.C. 371 National Phase Entry Application from PCT/KR2022/015179, filed Oct. 7, 2022, which claims the benefit of priority based on Korean Patent Application No. 10-2021-0134122 filed on Oct. 8, 2021 with the Korean Intellectual Property Office, the disclosures of which are incorporated herein by reference in their entirety.

### FIELD OF THE INVENTION

The present invention relates to a cover window of substrate-less type for a flexible display device, a flexible display device including the same, and a method for manufacturing thereof.

### BACKGROUND OF THE INVENTION

Recently, with the development of mobile devices such as smartphones and tablet PC, thinning and slimming of substrates for display are required. Glass or tempered glass is commonly used as a material having excellent mechanical properties on windows or front boards for displays of mobile devices. However, the glass and tempered glass are heavy int their own weight to cause the weight increase of the mobile devices, has a problem of being easily damaged by an external impact, has low flexibility and are limited in application to a flexible or foldable display device.

A cover window using a plastic resin is being studied as a material for replacing such glass. The plastic resin hardly has a risk of being broken while being lightweight, has flexibility and thus is more suitable for making mobile devices lighter and more flexible. Typically, polyethylene terephthalate (PET), polyethersulfone (PES), polyethylene naphthalate (PEN), polyacrylate (PAR), polycarbonate (PC), polyimide (PI), polyamideimide (PAI), and the like are used, but in the case of substrates using these plastic resins, they have the problems that hardness and scratch resistance are insufficient compared to glass materials. Thereby, attempts have been made to supplement high hardness and abrasion resistance by coating a resin composition onto a plastic resin substrate to form a hard coating layer.

However, the plastic resin substrate or cover window including a hard coating layer on the upper surface of the substrate has many difficulties in minimizing the difference in physical properties between the two layers while enhancing the interfacial adhesion between the substrate and the coating layer. In addition, there is a disadvantage in that the use of the substrate restricts the realization of a thin cover window, and the use of the plastic resin substrate increases the price of the optical sheet.

### BRIEF SUMMARY OF THE INVENTION

### Technical Problem

It is an object of the present invention to provide a cover window of substrate-less type for a flexible display device which does not include a support substrate and thus does not cause a peeling problem between the coating layer and the interface, and has high hardness and excellent flexibility, hardly has a risk of damage even by repetitive bending or folding operation, and thus, can be easily applied to bendable, flexible, rollable, or foldable mobile devices, display devices, and the like.

It is another object of the present disclosure to provide a flexible display device including the aforementioned cover window, and a method for manufacturing thereof.

### Technical Solution

Provided herein is a cover window of substrate-less type for a flexible display device, comprising: an organic-inorganic hardened layer including polysiloxane containing an epoxy group-containing functional group.

Also provided herein is a display device comprising: the cover window of substrate-less type for a flexible display device, an adhesive layer formed on one surface of the cover window, and a display panel formed on the adhesive layer.

Further provided herein is a method for manufacturing a display device comprising: a step of laminating a cover window of substrate-less type on one surface of a display panel, wherein the cover window of substrate-less type is made of an organic-inorganic hardened layer including polysiloxane containing an epoxy group-containing functional group.

### DETAILED DESCRIPTION OF THE INVENTION

Hereinafter, a cover window of substrate-less type for a flexible display device, a display device comprising the same, and a method for manufacturing thereof according to specific embodiments of the present invention will be described in more detail.

As used herein, the “flexible” means a state having flexibility to such an extent that cracks of 3 mm or more in length do not occur when wound around a cylindrical mandrel with a diameter of 5 mm. Therefore, the flexible display device of the present invention may mean a bendable, flexible, rollable, or foldable display device.

However, the embodiments are for illustrative purposes only, and are not meant to limit the scope of the invention, and it will be apparent to those skilled in the art that various modifications can be made to the embodiment without departing from the spirit or scope of the invention.

The technical terms used herein are only for mentioning specific embodiments and they are not intended to restrict the present invention, unless there is a particular mention about them.

Singular expressions used herein may include the plural expressions unless they are differently expressed contextually.

The meaning of the term “include” or “comprise” used herein embodies specific properties, areas, integers, steps, actions, elements, or components, and does not exclude existence or addition of other specific properties, areas, integers, steps, actions, elements, or components.

As used herein, the (meth)acrylate means not only methacrylate but also acrylate.

As used here, the weight average molecular weight means a weight average molecular weight in terms of polystyrene measured by GPC method. In the process of determining the weight average molecular weight in terms of polystyrene measured by the GPC method, a commonly known analyzing device, a detector such as a refractive index detector, and an analytical column can be used. Commonly applied conditions for temperature, solvent, and flow rate can be used. Specifically, the measurement was performed, for example, using Waters 2695. An evaluation temperature was 40° C., THE was used as a solvent, and the flow rate is 1 mL/min.

As used herein, the term “substituted or unsubstituted” means being unsubstituted or substituted with one or more substituents selected from the group consisting of deuterium; a halogen group; a nitrile group; a nitro group; a hydroxy group; a carbonyl group; an ester group; an imide group; an amino group; a phosphine oxide group; an alkoxy group; an aryloxy group; an alkylthioxy group; an arylthioxy group; an alkylsulfoxy group; an arylsulfoxy group; a silyl group; a boron group; an alkyl group; a cycloalkyl group; an alkenyl group; an aryl group; an aralkyl group; an aralkenyl group; an alkylaryl group; an alkylamine group; an aralkylamine group; a heteroarylamine group; an arylamine group; an arylphosphine group; and a heterocyclic group containing at least one of N, O and S atoms, or being unsubstituted or substituted with a substituent to which two or more substituents of the above-exemplified substituents are connected. For example, “a substituent in which two or more substituents are connected” may be a biphenyl group. Namely, a biphenyl group may be an aryl group, or it may be interpreted as a substituent in which two phenyl groups are connected.

According to an embodiment of the present invention, there can be provided a cover window of substrate-less type for a flexible display device, comprising: an organic-inorganic hardened layer including polysiloxane containing an epoxy group-containing functional group.

The present inventors have conducted intensive research on the cover window of a display device, and have found that when the cover window of substrate-less type is made of an organic-inorganic hardened layer including polysiloxane containing an epoxy group-containing functional group, and the thickness of such organic-inorganic hardened layer is 50 μm or more and less than 700 μm, it is possible to easily achieve a thin film, improve price competitiveness and simultaneously satisfy a physical property balance between flexibility and high hardness, thereby completing the present invention.

In addition, the cover window has almost no damage to the film even by repetitive bending or folding operation, and specifically when the organic-inorganic hardened layer is placed at an interval of 8 mm in the middle, and processes of folding and spreading the organic-inorganic hardened layer at a 90° angle to face each other are repeatedly performed 200,000 times at a rate of once per second at room temperature, a crack of 1 mm or more may not occur. Thereby, the cover window of substrate-less type can be easily applied to bendable, flexible, rollable, or foldable mobile devices, display devices, and the like using the same.

The cover window of substrate-less type serves as a support means for applying the composition for forming an organic-inorganic hardened layer, and refers to a support substrate that remains in a non-peeling state even after the composition for forming an organic-inorganic hardened layer is hardened. Therefore, the substrate-less type means not including such a support substrate.

The cover window according to the embodiment is of a substrate-less type, unlike a typical cover window, that is, it does not include a support substrate such as a plastic resin film that serves as a support means for the organic-inorganic hardened layer and does not peel even after hardening. Therefore, the cover window according to the one embodiment is of a substrate-less type film.

The cover window is a substrate-free type film made of an organic-inorganic hardened layer, but the organic-inorganic hardened layer may be a single layer or may be made of a plurality of layers. Further, another film, layer or film may be attached or coated onto the organic-inorganic hardened layer.

Further, since the cover window does not include a support substrate, it is not affected by the shrinkage of the substrate during the hardening process of the organic-inorganic hardened layer, so that there is no concern that curling or cracking will occur and there are no peeling problems that can occur at the interface with the substrate.

Further, even though the cover window does not include a support substrate, it has high hardness and excellent flexibility, and hardly has a damage even by repetitive bending or folding operation, and thus can be easily applied to a bendable, flexible, rollable, or foldable mobile device, a display device, or the like.

The cover window according to the one embodiment may be made of an organic-inorganic hardened layer including polysiloxane containing an epoxy group-containing functional group.

The polysiloxane containing the epoxy group-containing functional group may include two or more repeating units having different structures.

The polysiloxane may have various structures, for example, a structure of a cage-type polysilsesquioxane repeating unit, a ladder-type polysilsesquioxane repeating unit, or a random-type polysilsesquioxane repeating unit.

As the cover window according to the one embodiment includes polysiloxane including two or more repeating units having different structures, it may include a cage-type polysilsesquioxane repeating unit and a ladder-type polysilsesquioxane repeating unit, or may include a cage-type polysilsesquioxane repeating unit and a random-type polysilsesquioxane repeating unit, or may include a ladder-type polysilsesquioxane repeating unit and a random-type polysilsesquioxane repeating unit, or all of a cage-type polysilsesquioxane repeating unit, a ladder-type polysilsesquioxane repeating unit and a random-type polysilsesquioxane repeating unit.

More specifically, the polysiloxane containing two or more repeating units having different structures may include a cage-type polysilsesquioxane repeating unit and a ladder-type polysilsesquioxane repeating unit.

In the cover window of the one embodiment, as the organic-inorganic hardened layer includes both a cage-type polysilsesquioxane repeating unit and a ladder-type polysilsesquioxane repeating unit, the cage type with relatively small molecular weight increases hardening density to increase hardness, and linear ladder-type polysiloxane is widely distributed during the formation of the hardening network to increase flexibility and toughness, so that the cover window can exhibit a physical property balance between high flexibility and high hardness, as compared with the case including only one type of polysiloxane repeating unit of a cage-type polysilsesquioxane repeating unit or a ladder-type polysilsesquioxane repeating unit.

Further, the molar ratio of the cage-type polysilsesquioxane repeating unit to the ladder-type polysilsesquioxane repeating unit may be 1.2 or more and 2.5 or less, 1.2 or more and 2.0 or less, 1.2 or more and 1.8 or less, or 1.4 or more and 1.8 or less. As the molar ratio is 1.2 to 2.5, the cage type and the ladder shape can harmoniously form the composition, so that the cover window can exhibit a physical property balance between a high flexibility and a high hardness. Specifically, the cage-type polysilsesquioxane structure can increase the hardening density, making it possible to realize high hardness. The ladder-shaped polysilsesquioxane structure improves the flexibility of the hardened film through its flexible molecular structure. Therefore, as the cage-type polysilsesquioxane repeating unit and the ladder-type polysilsesquioxane repeating unit are included in the specific ratio, the physical properties of high flexibility and high hardness can be realized at the same time.

In the FT-IR (Fourier Transform-Infra Red) measured by an attenuated total reflection (ATR) method for the polysiloxane containing two or more repeating units having different structures, it has at least one peak in the region of 1010 cm⁻¹ to 1070 cm⁻¹, and at least one peak in the region of 1075 cm⁻¹ to 1130 cm⁻¹.

For example, in the FT-IR spectrum, it may exhibit at least one peak in the region of 1010 cm⁻¹ to 1070 cm⁻¹, 1030 cm⁻¹ to 1065 cm⁻¹ or 1040 cm⁻¹ to 1060 cm⁻¹ and may exhibit at least one peak in the region of 1075 cm⁻¹ to 1130 cm⁻¹, 1080 cm⁻¹ to 1110 cm⁻¹ or 1090 cm⁻¹ to 1100 cm⁻¹.

The polysiloxane containing epoxy group-containing functional groups can contain at least two repeating units having different structures, as they each have peaks in different regions of the FT-IR spectrum.

Specifically, in the region of 1010 cm⁻¹ to 1070 cm⁻¹, it may exhibit two or more peaks or may exhibit only one peak, and the peak appearing in the region of 1010 cm⁻¹ to 1070 cm⁻¹ may be a peak related to the ladder-type polysiloxane and/or the random-type polysiloxane. Further, in the region of 1075 cm⁻¹ to 1130 cm⁻¹, it may exhibit two or more peaks or may exhibit only one peak, and the peak appearing in the region of 1075 cm⁻¹ to 1130 cm⁻¹ may be a peak related to the cage-type polysiloxane.

Further, the peak intensity ratio (I₂/I₁) of an intensity (I₂) for the highest intense peak among at least one peak appearing in the region of 1075 cm⁻¹ to 1130 cm⁻¹ to an intensity (I₁) for the highest intense peak among at least one peak appearing in the region of 1010 cm⁻¹ to 1070 cm⁻¹ may be 1.2 or more and 2.5 or less, 1.2 or more and 2.0 or less, 1.2 or more and 1.8 or less, or 1.4 or more and 1.8 or less.

The intensity (I₁) of the peak means the intensity for the highest intense peak when two or more peaks appearing in the region of 1010 cm⁻¹ to 1070 cm⁻¹, and means the intensity for the corresponding peak when one peak appears. Also, the intensity (I₂) of the peak means the intensity for the highest intense peak when two or more peaks appear in the region of 1075 cm⁻¹ to 1130 cm⁻¹, and means the intensity for the corresponding peak when one peak appears.

The peak intensity ratio (I₂/I₁) can be measured in an FT-IR spectrum using an ATR method using, as a sample, a polysiloxane in non-hardened state before going through the hardening process or in a solid state after hardening.

As the peak intensity ratio (I₂/I₁) is 1.2 to 2.5, the cage and the ladder shape allow the composition to harmoniously form, so that the cover window can exhibit a physical property balance between high flexibility and high hardness. When the peak intensity ratio (I₂/I₁) is less than 1.2 or more than 2.5, flexibility is deteriorated and hardness is also reduced, so that the physical properties sufficient for use as a cover window of a flexible display device cannot be achieved.

Meanwhile, the polysiloxane containing the epoxy group-containing functional group may include 70 mol % or more of the repeating unit containing an epoxy group-containing functional group.

The epoxy group-containing functional group is not particularly limited as long as it is a functional group containing an epoxy group, but may be, for example, any one selected from the group consisting of an alicyclic epoxy group and a functional group represented by the following Chemical Formula 1.

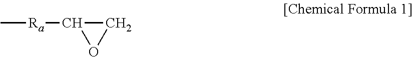

wherein, in Chemical Formula 1,
Rₐ is a substituted or unsubstituted alkylene group having 1 to 6 carbon atoms, a substituted or unsubstituted alkenylene group having 2 to 20 carbon atoms, a substituted or unsubstituted alkynylene group having 2 to 20 carbon atoms, —R_{b}—CH═CH—COO—R_{c}—, —R_{d}—OCO—CH═CH—Rₑ—, —R_{f}OR_{g}—, —RₕCOORᵢ—, or —RⱼOCORₖ—, and
R_{b} to Rₖ are each independently a single bond; or a substituted or unsubstituted alkylene group having 1 to 6 carbon atoms.

The functional group represented by Chemical Formula 1 not only includes an epoxy group and thus, improves physical properties of high hardness and scratch resistance of the cover window, but also has almost no damage to the film even by repetitive bending or folding operation, and thus, can be easily applied to a bendable, flexible, rollable, or foldable mobile device, a display device, or the like.

For example, the epoxy group-containing functional group Rₐ represented by Chemical Formula 1 may be methylene, ethylene, propylene, allylene, —R_{b}—CH═CH—COO—R_{c}—, —R_{d}—OCO—CH═CH—Rₑ—, —R_{f}OR_{g}—, —RₕCOORᵢ—, or —RⱼOCORₖ—.

For example, R_{b} to Rₖ in Chemical Formula 1 may be a single bond, methylene, ethylene, propylene, or butylene.

For example, Rₐ may be methylene, ethylene, or —R_{f}OR_{g}—, wherein R_{f} and R_{g} may be a direct bond, methylene or propylene.

For example, the functional group represented by Chemical Formula 1 is not limited thereto, but may be glycidoxy, glycidoxyethyl group, glycidoxypropyl group or glycidoxybutyl group.

Further, the alicyclic epoxy group is not limited thereto, but may be, for example, epoxycyclohexyl.

Further, the polysiloxane may be represented by the following Chemical Formula 2.

(R⁷SiO_{3/2})ₐ(R⁸SiO_{3/2})_{b}(R⁹R¹⁰SiO_{2/2})_{c}(R¹¹R¹²R¹³SiO_{1/2})_{d}(SiO_{4/2})ₑ(O_{1/2}R¹⁴)_{f} [Chemical Formula 2]
wherein, in Chemical Formula 2,
R⁷ to R¹³ are each independently hydrogen, an epoxy group-containing functional group, an amino group, a mercapto group, an ether group, an ester group, a carbonyl group, a carboxyl group, a (meth)acrylate, a sulfone group, a substituted or unsubstituted alkyl group having 1 to 20 carbon atoms, a substituted or unsubstituted cycloalkyl group having 3 to 20 carbon atoms, a substituted or unsubstituted alkenyl group having 2 to 20 carbon atoms, a substituted or unsubstituted alkynyl group having 2 to 20 carbon atoms, a substituted or unsubstituted alkoxy group having 2 to 20 carbon atoms, a substituted or unsubstituted aryl group having 6 to 20 carbon atoms, a substituted or unsubstituted arylalkyl group having 7 to 20 carbon atoms, or a substituted or unsubstituted alkylaryl group having 7 to 20 carbon atoms, provided that at least one of R⁷ to R¹³ is the epoxy group-containing functional group,
R¹⁴ is a hydrogen atom or an alkyl group having 1 to 20 carbon atoms, and
0<a≤1, 0≤b≤1, 0≤c≤1, 0≤d≤1, 0≤e≤1, 0≤f≤1.
R⁷ may be the epoxy group-containing functional group, and may include 70 mol % or more of the repeating unit containing the substituent of R⁷ with respect to the total molar ratio content of Chemical Formula 2. When the content of the repeating unit containing the functional group represented by Chemical Formula 1 is less than 70 mol %, there is a problem that it is difficult for the organic-inorganic hardened layer to exhibit sufficient surface hardness due to the decrease in the hardening density.

The polysiloxane represented by Chemical Formula 2 may include (R⁷SiO_{3/2}) structural unit, (R⁸SiO_{3/2}) structural unit, (R⁹R¹⁰SiO_{2/2}) structural unit, (R¹¹R¹²R¹³SiO_{1/2}) structural unit, (SiO_{4/2}) structural unit, and (O_{1/2}R¹⁴) structural unit. Further, in Chemical Formula 2, the molar ratio of the structural units described above is represented by a, b, c, d, e, and f, respectively. At this time, each molar ratio is 0<a≤1, 0≤b≤1, 0≤c≤1, 0≤d≤1, 0≤e≤1, 0≤f≤1, provided that their sum (a+b+c+d+e+f) may be 1.

Further, R⁷ may be the epoxy group-containing functional group, wherein the molar ratio of the (R⁷SiO_{3/2}) structural unit may be 0.7<a≤1, 0.7<a≤0.99, and 0.8<a≤0.9.

Further, the (R⁷SiO_{3/2}) structural unit and (R⁸SiO_{3/2}) structural unit included in the polysiloxane are structural units in which three siloxane bonds are formed, and the polysiloxane containing them can increase the hardening density and improve the surface hardness properties of the organic-inorganic hardened layer.

Further, the (R⁹R¹⁰SiO_{2/2}) structural unit contained in the polysiloxane is a structural unit in which two siloxane bonds are formed, and the molar ratio of the (R⁹R¹⁰SiO_{2/2}) structural unit is c, wherein the molar ratio of the (R⁹R¹⁰SiO_{2/2}) structural unit to the total molar ratio of the polysiloxane of Chemical Formula 2 may be 0≤c≤1, 0.01≤c<0.3, or 0.05≤c≤0.2 as described above.

Further, the (R¹¹R¹²R¹³SiO_{1/2}) structural unit contained in the polysiloxane is a structural unit in which one siloxane bond is formed, and the molar ratio of the (R¹¹R¹²R¹³SiO_{1/2}) structural unit is d, wherein the molar ratio of the (R¹¹R¹²R¹³SiO_{1/2}) structural unit to the total molar ratio of the polysiloxane of Chemical Formula 2 may be 0≤d≤1, 0.01≤d<0.3, or 0.05≤d≤0.2 as described above.

Further, the sum (c+d) of the molar ratios of the (R⁹R¹⁰SiO_{2/2}) structural unit and the (R¹¹R¹²R¹³SiO_{1/2}) structural unit may be 0≤c+d<0.3, 0.01≤c+d<0.29, 0.05≤c+d≤0.25, or 0.07≤c+d≤0.23. The sum (c+d) of the molar ratios of the (R⁹R¹⁰SiO_{2/2}) structural unit and the (R¹¹R¹²R¹³SiO_{1/2}) structural unit may be 0.3 or more.

Specifically, R⁷ is an epoxy group-containing functional group, R⁸ to R¹³ may be hydrogen, an amino group, a mercapto group, an ether group, an ester group, a carbonyl group, a carboxyl group, a (meth)acrylate, a sulfone group, a methyl group, an ethyl group, a propyl group, a t-butyl group, a cyclohexyl group, a methoxy group, an ethoxy group, a propoxy group, a t-butoxy group, a phenyl group, a naphthalene group, and the like.

The polysiloxane may include a (SiO_{4/2}) structural unit, which is a structural unit in which four siloxane bonds are formed. Further, the molar ratio of the (SiO_{4/2}) structural unit is e, wherein e may be 0≤e≤1, 0.01≤e<0.3, or 0.05≤e≤0.2.

Further, the polysiloxane may include a (O_{1/2}R¹⁴) structural unit, and polysiloxane including the same may improve flexibility while maintaining excellent hardness properties. Further, the molar ratio of the (O_{1/2}R¹⁴) structural unit is f, wherein f may be 0≤f≤1, 0.01≤f<0.3, or 0.05≤f≤0.2.

The R¹⁴ may be a hydrogen atom or an alkyl group having 1 to 20 carbon atoms, and more specifically, it may be a hydrogen atom, an ethyl group, a propyl group, an isopropyl group, a butyl group, an isobutyl group, or the like.

Polysiloxane containing the above-mentioned structural units can be prepared by hydrolysis and condensation reactions of siloxane monomer of each structural unit, specifically, an alkoxysilane having a functional group of Chemical Formula 1 alone, or between an alkoxysilane having a functional group of Chemical Formula 1 and a different alkoxysilane, wherein the molar ratio of each structural unit may be controlled through control of the content ratio of the alkoxysilane. Meanwhile, the content of each structural unit constituting the polysiloxane may be obtained by measurement of ¹H-NMR or ²⁹Si-NMR spectrum.

Meanwhile, the polysiloxane may have an equivalent weight of the epoxy group-containing functional group of 3.0 to 6.3 mmol/g or 4.0 to 6.0 mmol/g. When the equivalent weight of the functional group represented by Chemical Formula 1 is too small, the density of the organic-inorganic hardened layer decreases, which causes a problem that the surface hardness is lowered, and when the equivalent weight is too high, there is a problem that the flexibility is lowered and the unhardened epoxy remains which lowers the environmental reliability. The equivalent weight of these functional groups is a value obtained by dividing the molecular weight of the polysiloxane by the number of functional groups, and can be analyzed by H-NMR or chemical titration method.

Further, the polysiloxane can adjust the weight average molecular weight, the number average molecular weight, the molecular weight distribution, and the like by adjusting the reaction rate using the reaction temperature, the amount of catalyst, the type of solvent, and the like. The above-mentioned polysiloxane may have a weight average molecular weight of 1,000 to 50,000 g/mol, or 1,200 to 15,000 g/mol. By having a weight average molecular weight within the above range, more excellent hardness properties can be exhibited. If the weight average molecular weight is less than 1,000 g/mol, the hardness is not realized, and rather ductility may be expressed. Moreover, if the weight average molecular weight exceeds 50,000 g/mol, high hardness is exhibited, but there exists a possibility that film processability may deteriorate.

Further, the polysiloxane may have a number average molecular weight (Mn) of 1,000 to 10,000 g/mol, more specifically, 1,000 to 8,000 g/mol in addition to the above-mentioned Mw. When the above-mentioned number average molecular weight condition is satisfied, the compatibility with other components in the composition for forming an organic-inorganic hardened layer is increased, the surface hardness of the hardened product is improved, and the heat resistance and abrasion resistance of the hardened product can be further improved. Meanwhile, the weight average molecular weight and the number average molecular weight of the polysiloxane are standard polystyrene conversion values obtained by gel permeation chromatography.

Further, the polysiloxane may have a molecular weight distribution (Mw/Mn) of 1.0 to 10.0, more specifically, 1.1 to 5.0. When it has a molecular weight distribution within the above range, the effect of improving the surface hardness is more excellent, and the polysiloxane exists in a liquid state, and it easy to handle.

The cover window according to the embodiment is made of an organic-inorganic hardened layer, wherein the organic-inorganic hardened layer may include an elastomeric polymer. The elastomeric polymer imparts stress resistance properties through the toughness of the cover window made of an organic-inorganic hardened layer, and can minimize shrinkage during hardening, thereby improving bending properties and at the same time improving flexibility such as bendability, and improving hardness properties.

The elastomeric polymer may be contained specifically in an amount of 10 parts by weight or more and 80 parts by weight or less, 10 parts by weight or more and 70 parts by weight or less, 10 parts by weight or more and 60 parts by weight or less, and 15 parts by weight or more and 50 parts by weight or less with respect to 100 parts by weight of the polysiloxane containing the epoxy group-containing functional group. If the content of the elastomeric polymer is too large, there is a risk that the surface hardness property may be deteriorated, and if the content of the elastomeric polymer is too small, the improvement effect due to the inclusion of the elastomeric polymer may not be sufficiently obtained, and there is a risk that the bending property and the bendability may be deteriorated.

The elastomeric polymer is not limited thereto, but for example, it may include at least one selected from the group consisting of an alkanediol having 1 to 20 carbon atoms, polyolefin polyol, polyester polyol, polycaprolactone polyol, polyether polyol and polycarbonate polyol. These elastomeric polymers can be crosslinked and polymerized by UV irradiation compared to conventional elastomeric polymers such as rubber, and can realize high hardness and flexibility without deteriorating other physical properties.

Among them, the elastomeric polymer may be polycaprolactone polyol. The polycaprolactone polyol s repeated containing both an ester group and an ether group in a repeating unit, so that when used in combination with the polysiloxane, it is possible to exhibit more excellent effects in terms of flexibility, hardness, and impact resistance.

The elastomeric polymer may have a number average molecular weight (Mn) of 300 Da or more and 10,000 Da or less, or 500 Da or more and 5,000 Da or less. When the above number average molecular weight conditions are satisfied, the compatibility with other components in the organic-inorganic hardened layer is increased, and the surface hardness of the hardened product is improved, and thus, heat resistance and abrasion resistance of the hardened product can be further improved.

The organic-inorganic hardened layer may further include a reactive monomer including at least one functional group crosslinkable with the polysiloxane. The reactive monomer includes at least one functional group crosslinkable with the polysiloxane described above, and serves as a crosslinking agent between the polysiloxane networks, thereby increasing the tensile strength of the organic-inorganic hardened layer.

The reactive monomer is a functional group crosslinkable with the polysiloxane, and for example, it may include at least one selected from the group consisting of an alicyclic epoxy group, a glycidyl group, and an oxetanyl group.

In addition, the reactive monomer containing at least one functional group crosslinkable with the polysiloxane may include, for example, at least one selected from the group consisting of bisphenol A diglycidyl ether, 4-vinylcyclohexene dioxide, cyclohexene vinyl monoxide, (3,4-epoxycyclohexyl)methyl 3,4-epoxycyclohexylcarboxylate, 3,4-epoxycyclohexylmethyl methacrylate, 3,4-epoxycyclohexanecarboxylate, 2-(3,4-epoxycyclohexyl)-1,3-dioxolane, bis(3,4-epoxycyclohexylmethyl)adipate, p-butyl phenol glycidyl ether, butyl glycidyl ether, cresyl glycidyl ether, allyl glycidyl ether, phenyl glycidyl ether, diglycidyl ether, butanediol diglycidyl ether, limonene dioxide, diethylene glycol diglycidyl ether, 3-methyloxetane, 2-methyloxetane, 3-oxetanol, 2-methyleneoxetane, 3-methyl-3-hydroxymethyloxetane, 3-ethyl-3-hydroxymethyloxetane, 3,3-oxetanedimethanethiol, 2-ethylhexyloxetane, 4-(3-methyloxetan-3-yl)benzonitrile, N-(2,2-dimethylpropyl)-3-methyl-3-oxetanemethanamine, N-(1,2-dimethylbutyl)-3-methyl-3-oxetanemethanamine, xylene bis oxetane, 3-ethyl-3[{(3-ethyloxetan-3-yl)methoxy}methyl]oxetane, (3-ethyloxetan-3-yl)methyl methacrylate, and 4-[(3-ethyloxetan-3-yl)methoxy]butan-1-ol.

The weight ratio of the polysiloxane and the reactive monomer included in the organic-inorganic hardened layer may be 99:1 to 70:30, 95:5 to 73:27, 90:10 to 75:25, or 85:15 to 76:24. When the polysiloxane is included in an excessive amount compared to the reactive monomer, the improvement effect due to the inclusion of the reactive monomer may be insignificant. On the other hand, when the polysiloxane is included in an excessively small amount compared to the elastomeric polymer, the distance between hardening sites is narrowed due to an excess of reactive monomer and due to the hardening shrinkage resulting therefrom, the internal stress of the coating film may increase, thereby reducing crack resistance.

The organic-inorganic hardened layer may further include an acrylate-based compound to improve surface hardness.

The acrylate-based compound may include 2-ethylhexyl acrylate, octadecyl acrylate, isodecyl acrylate, 2-phenoxyethyl acrylate, lauryl acrylate, stearyl acrylate, behenyl acrylate, tridecyl methacrylate, nonylphenol ethoxylate monoacrylate, β-carboxyethyl acrylate, isobornyl acrylate, tetrahydrofurfuryl acrylate, tetrahydrofurfuryl methacrylate, 4-butylcyclohexyl acrylate, dicyclopentenyl acrylate, dicyclopentenyl oxyethyl acrylate, ethoxyethoxyethyl acrylate, ethoxylated monoacrylate, 1,6-hexanediol diacrylate, triphenylglycol diacrylate, butanediol diacrylate, 1,3-butylene glycol dimethacrylate, 1,6-hexanediol dimethacrylate, neopentyl glycol diacrylate, ethylene glycol dimethacrylate, diethylene glycol diacrylate, diethylene glycol dimethacrylate, tetraethylene glycol diacrylate, tetraethylene glycol dimethacrylate, triethylene glycol diacrylate, triethylene glycol dimethacrylate, polyethylene glycol diacrylate, polyethylene glycol dimethacrylate, diporophylene glycol diacrylate, ethoxylated neopentyl glycol diacrylate, trimethylolpropane triacrylate, trimethylolpropane trimethacrylate, pentaerythritol triacrylate, pentaerythritol trimethacrylate, pentaerythritol tetramethacrylate, pentaerythritol tetraacrylate, ethoxylated triacrylate, tris(2-hydroxyethyl)isocyanurate triacrylate, dipentaerythritol pentaacrylate, ditrimethylolpropane tetraacrylate, alkoxylated tetraacrylate, and the like. Preferably, it may include polyfunctional acrylate compound such as pentaerythritol triacrylate, pentaerythritol trimethacrylate, pentaerythritol tetramethacrylate, pentaerythritol tetraacrylate, or the like. One or mixtures of two or more types thereof may be used.

In addition, it may include acrylate-based oligomers such as polyester acrylate, polyether acrylate, urethane acrylate, epoxy acrylate, or the like, and one or mixtures of two or more types thereof may be used. Considering the remarkable effect of improving the surface hardness when used in combination with the above-mentioned polysiloxane among the acrylate-based compounds, a urethane acrylate oligomer can be used more preferably.

The urethane acrylate oligomer may have 6 to 9 functional groups. If the number of the functional group is less than 6, the effect of improving hardness may be insignificant, and if the number of the functional group is more than 9, the hardness is excellent, but the viscosity may increase. In addition, as the urethane (meth)acrylate oligomer, those used in the relevant field can be used without limitation, but preferably, those prepared by reacting a compound having at least one isocyanate group in the molecule with a (meth)acrylate compound having at least one hydroxyl group in the molecule can be used.

When the acrylate-based compound is further included, it may be contained in an amount of 0.1 to 20 parts by weight, 1 to 15 parts by weight, or 5 to 10 parts by weight based on 100 parts by weight of the polysiloxane. When the content of the reactive monomer is less than 0.1 parts by weight, the improvement effect due to the inclusion of the acrylate-based compound is insignificant, and when the content of the reactive monomer is more than 20 parts by weight, the effect of improving the surface hardness may be rather inhibited due to an excess of the acrylate-based compound.

The organic-inorganic hardened layer may further include an initiator, a sensitizer, and the like used for photocuring or thermal curing.

Together with the above components, the organic-inorganic hardened layer may independently further include one or more commonly used additives such as antioxidants, surfactants, anti-yellowing agents, inorganic nanoparticles, lubricants, coating aids, antifouling agents, dispersants, light absorbers, pigments, dyes, and the like.

Examples of the inorganic nanoparticles that can be used include silica fine particles, aluminum oxide particles, titanium oxide particles, zinc oxide particles, or the like.

Further, the particle size of the inorganic nanoparticles may be 10 to 200 nm, 30 to 180 nm, 50 to 150 nm, or 60 to 130 nm. The particle size range of these inorganic nanoparticles may be measured with a transmission electron microscope (TEM).

The inorganic nanoparticles may include a predetermined functional group substituted on the surface in order to be more easily dispersed in an organic solvent. Examples of the organic functional groups that can be substituted on the surfaces of the inorganic nanoparticles are not particularly limited, and for example, a (meth)acrylate group, a vinyl group, a hydroxyl group, an amine group, an allyl group, an epoxy group, a hydroxyl group, an isocyanate group, an amine group, fluorine, or the like can be substituted on the surface of the inorganic nanoparticles.

Meanwhile, the cover window of substrate-less type for a display device according to the embodiment is made of an organic-inorganic hardened layer, and the thickness of the organic-inorganic hardened layer may be 50 μm or more and 1,000 μm or less, 50 μm or more and less than 700 μm, 50 μm or more and less than 500 μm, 50 μm or more and less than 300 μm, 60 μm or more and 250 μm or less, 70 μm or more and 230 μm or less, 100 μm or more and 200 μm or less. The cover window is made of only an organic-inorganic hardened layer without including a support substrate, and thus, it is possible to realize a cover window having a thinner thickness than in the conventional one. Even in such a thin thickness range, it is possible to simultaneously satisfy a physical property balance between flexibility and high hardness, and prevent damage to the internal structure caused by repetitive bending or folding operation.

In addition, since the cover window does not include a support substrate, even if the organic-inorganic hardened layer itself is formed to have a slightly high thickness, it is not affected by the shrinkage of the substrate, and thus there is no fear of curling or cracking.

The organic-inorganic hardened layer may be a single layer or a multilayer structure of two or more layers. When the organic-inorganic hardened layer has a multilayer structure, the sum of the total thickness of the entire organic-inorganic hardened layer is not particularly limited, but for example, it may be 50 μm or more and 1,000 μm or less, 50 μm or more and 900 μm or less, 100 μm or more and 800 μm or less, 200 μm or more and 700 μm or less, 200 μm or more and 600 μm or less.

The cover window of substrate-less type for a display device of the one embodiment does not generate cracks of 1 mm or more, when the organic-inorganic hardened layer is placed at an interval of 8 mm in the middle, and processes of folding and spreading the organic-inorganic hardened layer at a 90° angle to face each other are repeatedly performed 200,000 times at a rate of once per second at room temperature. Thus, it has almost no damage to the film even by repetitive bending or folding operation, and thus can be easily applied to a cover window of a bendable, flexible, rollable, or foldable mobile device or a display device, or the like.

FIG. 1 schematically shows a method for evaluating dynamic bending properties.

Referring to FIG. 1, the cover window for a flexible display device is placed so as to be horizontal with the bottom, and set so that the distance between the portions folded at a middle portion of the film is 8 mm, and the processes of folding and spreading both sides of the cover window at a 90° angle are repeatedly performed 200,000 times at a rate of once per second at room temperature. By such a method, the durability against bending can be measured. At this time, in order to maintain the distance between the folding portions constant, for example, the cover window is placed so as to be in contact with a rod having a diameter (R) of 8 mm, the remaining portion of the cover window is fixed, and the processes of folding and spreading both sides of the cover window around the rod can be performed. Further, the folded portion is not particularly limited as long as it is the inside of the cover window, and for convenience of measurement, the central portion of the cover window may be folded so that the remaining portions of the cover window excluding the folded portion are symmetrical.

In evaluating such dynamic bending property, the cover window for a flexible display device does not a crack 1 cm or more, or 1 mm or more after bending operation is performed 200,000 times, and it is virtually crack-free. Therefore, even in actual application conditions such as repeatedly folding, rolling or warping, the possibility of occurrence of cracks is extremely low, and thus it can be suitably applied to the cover window for a flexible display device.

After the adhesive layer and the functional layer are formed on one surface of the cover window, or in the assembled state of the panel, the cover window moves back and forth five times under a load of 300 g using a pencil hardness tester against the surface of the cover window, and the maximum hardness without cracks on the path passed by the pencil may be 2B or more, 2B or more and 5H or less, B or more and 5H or less, or H or more and 5H or less.

For this reason, the cover window implements excellent compression resistance, and hardly has a damage to the film even by repetitive bending or folding operation, and realizes device stability, and thus can be easily applied to a cover window for a flexible display device and a bendable, flexible, rollable, or foldable mobile device using the same, or a display device.

Meanwhile, according to another exemplary embodiment of the disclosure, a display device including the cover window of substrate-less type for a flexible display device, an adhesive layer formed on one surface of the cover window, and a display panel formed on the adhesive layer. The display device may be a flexible display device.

The display panel includes a curved, bendable, flexible, rollable or foldable-shaped mobile communication terminal, a touch panel of a smartphone or a tablet PC, and various display panels.

For example, the display panel may be an organic light emitting diode (OLED) display panel, a quantum-dot light emitting diode display panel, or an inorganic light emitting diode display panel in an electroluminescent display.

When the display panel is a liquid crystal display panel, it includes a plurality of gate lines and data lines, and pixels formed at intersection regions of the gate lines and the data lines. It can be configured by including an array substrate including a thin film transistor, which is a switching element for adjusting the light transmittance in each pixel, an upper substrate having a color filter and/or a black matrix, and the like, and a liquid crystal layer formed between the array substrate and the upper substrate,

Further, when the display panel is an organic electroluminescence (OLED) display panel, it may include a plurality of gate lines and data lines, and pixels formed at intersection regions of gate lines and data lines. It may be configured by including an array substrate including a thin film transistor, which is an element for selectively applying a voltage to each pixel, an organic light emitting device (OLED) layer on the array substrate, and a sealing substrate or an encapsulation substrate disposed on the array substrate to cover the organic light emitting device layer, etc. The encapsulation substrate may protect the thin film transistor and the organic light emitting device layer from external impact, and may prevent penetration of moisture or oxygen into the organic light emitting device layer. The layer formed on the array substrate may include an inorganic light emitting layer, for example, a nano-sized material layer or quantum dots, or the like.

The cover window of substrate-less type for a display device may be made of a transparent material to transmit light emitted from the display panel.

Further, the cover window of substrate-less type for a display device may be coupled due to an adhesive layer interposed therebetween, and the adhesive may include an optical clear adhesive (OCA or Optical Clear Resin; OCR).

According to yet another embodiment of the disclosure, there can be provided a method for manufacturing a display device comprising: a step of laminating a cover window of substrate-less type on one surface of a display panel, wherein the cover window of substrate-less type is made of an organic-inorganic hardened layer including polysiloxane containing an epoxy group-containing functional group. The display device may be a flexible display device.

The thickness of the organic-inorganic hardened layer may be 50 μm or more and less than 300 μm. The composition (polysiloxane containing an epoxy group-containing functional group, etc.) and the structure of the cover window included in the organic-inorganic hardened layer are the same as those described above for the cover window according to the one embodiment.

The method for manufacturing the display device may include the following steps:
Step 1) forming an organic-inorganic hardened layer including polysiloxane containing an epoxy group-containing functional group on one surface of a release film;
Step 2) peeling the release film from the organic-inorganic hardened layer;
Step 3) forming an adhesive layer on one surface of the organic-inorganic hardened layer from which the release film has been peeled or on one surface of the display panel; and
Step 4) laminating a cover window of substrate-less type on one surface of the display panel.

At this time, the display panel and the cover window made of the organic-inorganic hardened layer may be laminated due to an adhesive layer interposed therebetween.

Further, the method for manufacturing the display device may include the following steps:
Step A) preparing a release film where an adhesive layer is formed on one surface;
Step B) forming an organic-inorganic hardened layer including polysiloxane containing an epoxy group-containing functional group on the adhesive layer;
Step C) peeling the release film; and
Step D) laminating a cover window of substrate-less type on one surface of the display panel.

At this time, the display panel and the cover window made of the organic-inorganic hardened layer are laminated due to an adhesive layer interposed therebetween.

The release film may be used without limitation as long as it is commonly used in the technical field to which the present invention belongs, and examples thereof include a polyolefin-based film or a Teflon-based film such as a polyester film, a polyethylene film, a polyethylene terephthalate film, and a polypropylene film, and preferably, it may be a film release-treated with silicone or acrylic silicone so that it can be easily peeled.

The release film may be formed to a thickness of 10 μm to 500 μm, or 20 μm to 200 μm, but is not limited thereto.

The organic-inorganic hardened layer including the polysiloxane may be formed on a release film or an adhesive layer formed on one surface of the release film, and for example, it may be provided by applying a composition for forming an organic-inorganic hardened layer and photocuring the composition.

The method of applying the composition for forming the organic-inorganic hardened layer is not particularly limited as long as it can be used in the technical field to which the present technology belongs, and for example, a bar coating method, a knife coating method, a roll coating method, a blade coating method, a die coating method, a micro gravure coating method, a comma coating method, a slot die coating method, a lip coating method, a solution casting method, or the like can be used.

In addition, the irradiation dose of ultraviolet rays during photocuring of the organic-inorganic hardened layer may be, for example, about 100 to about 2000 mJ/cm², or about 500 to about 1000 mJ/cm². The light source of ultraviolet irradiation is not particularly limited as long as it can be used in the technical field to which this technology belongs, and for example, a high-pressure mercury lamp, a metal halide lamp, a black light fluorescent lamp, or the like can be used. The photocuring step may be performed by irradiating for about 30 seconds to about 15 minutes, or about 1 minute to about 10 minutes at the irradiation dose as described above.

After forming the organic-inorganic hardened layer, the release film is peeled, and the display panel and the cover window made of the organic-inorganic hardened layer may be laminated with an adhesive layer interposed therebetween.

The display panel is the same as those described above in the display panel of the display device according to another embodiment.

### Advantageous Effects

According to the present invention, there can be provided a cover window of substrate-less type for a flexible display device and a flexible display device which do not include a support substrate and thus can easily achieve a thin film without causing a peeling problem between the coating layer and the interface, improve price competitiveness and simultaneously satisfy a physical property balance between flexibility and high hardness, particularly have almost no risk of damaging the film even by repetitive bending or folding operation, and thus, can be easily applied to bendable, flexible, rollable, or foldable mobile devices, display devices, and the like.

Since the cover window for the flexible display device may have physical properties that can replace tempered glass or the like, not only it is not broken by pressure or force applied from the outside, but also it can have the properties capable of being sufficiently bent and folded, and exhibits flexibility, bending property, high hardness, scratch resistance, high transparency, anti-fingerprint and antifouling properties, and hardly has a risk of damaging the film even in repetitive, continuous bending or long-time folding state. Therefore, the cover window can be usefully applied to bendable, flexible, rollable or foldable mobile devices, display devices, front face and display unit of various instrument panels, and the like.

### BRIEF DESCRIPTION OF THE DRAWINGS

FIG. 1 schematically shows a method for evaluating dynamic bending properties.

### DETAILED DESCRIPTION OF THE EMBODIMENTS

Hereinafter, the present invention will be described in more detail by way of examples. However, these examples are merely presented for illustrative purposes only, and the scope of the invention is not determined thereby.

### Preparation Example 1

(1) Preparation of Polysiloxane A

3-Glycidoxypropyltrimethoxysilane (GPTMS, KBM-403™, ShinEtsu) which is a silane monomer, water and toluene were added to a 1000 mL 3-neck flask, mixed and stirred (GPTMS:water=1 mol: 3 mol).

Next, a basic catalyst (trimethylammonium hydroxide; TMAH) was added to the resulting mixed solution in an amount of 1 part by weight based on 100 parts by weight of the silane monomer, and reacted at 100° C. for 2 hours to prepare polysiloxane A having the following composition containing 100 mol % of glycidoxypropyl modified silicone (hereinafter, referred to as GP).

In the FT-IR spectrum measured by the ATR method for polysiloxane A, a peak intensity ratio (I₂/I₁) of the intensity (I₂) for the peak appearing at 1090 cm⁻¹ to the intensity (I₁) for the peak appearing at 1055 cm⁻¹ was shown to be 1.45.

(2) Preparation of a Composition for Forming an Organic-Inorganic Hardened Layer

100 g of the polysiloxane A, 50 g of an elastomeric polymer (polycaprolactone diol, Mn=530), 3 g of an initiator I-250 (BASF), 0.2 g of leveling agent F-477 (DIC) and 10 g of methyl ethyl ketone as a solvent were mixed to prepare a composition for forming an organic-inorganic hardened layer.

### Comparative Preparation Example 1

(1) Preparation of Polysiloxane B

3-Glycidoxypropyltrimethoxysilane (GPTMS, KBM-403™, ShinEtsu) which is a silane monomer, water and toluene were added to a 1000 mL 3-neck flask, mixed and stirred (GPTMS:water=1 mol: 3 mol).

Next, a basic catalyst (trimethylammonium hydroxide; TMAH) was added to the resulting mixed solution in an amount of 1 part by weight based on 100 parts by weight of the silane monomer, and reacted at 100° C. for 8 hours to prepare polysiloxane B having the following composition containing 100 mol % of glycidoxypropyl modified silicone (hereinafter, referred to as GP).

In the FT-IR spectrum measured by the ATR method for polysiloxane B, a peak intensity ratio (I₂/I₁) of the intensity (I₂) for the peak appearing at 1090 cm⁻¹ to the intensity (I₁) for the peak appearing at 1020 cm⁻¹ was shown to be 1.15.

(2) Preparation of a Composition for Forming an Organic-Inorganic Hardened Layer

100 g of the polysiloxane B, 50 g of an elastomeric polymer (polycaprolactone diol, Mn=530), 3 g of an initiator 1-250 (BASF), 0.2 g of leveling agent F-477 (DIC) and 10 g of methyl ethyl ketone as a solvent were mixed to prepare a composition for forming an organic-inorganic hardened layer.

### Examples and Comparative Examples

### Examples 1 to 3, Comparative Examples 1 and 2

A release-treated polyethylene terephthalate (PET, Mitsubishi) release film having a thickness of 100 μm was prepared. A composition for forming an organic-inorganic hardened layer was applied to one surface of the release film, and pothohardened by irradiating ultraviolet light using a lamp (irradiation dose: 1,000 mJ/cm²) to form an organic-inorganic hardened layer. Then, the release film was peeled from the organic-inorganic hardened layer to manufacture a cover window of substrate-less type for a display device.

At this time, the composition for forming an organic-inorganic hardened layer and the thickness of the organic-inorganic hardened layer used in each of Examples and Comparative Examples are as shown in Table 1 below.

### Comparative Example 3

The composition for forming an organic-inorganic hardened layer prepared in Preparation Example 1 was applied to one surface of a polyethylene terephthalate (PET) film with a size of 15 cm×20 cm and a thickness of 50 μm, and photocured by irradiating ultraviolet light using a lamp (irradiation dose: 1,000 mJ/cm²) to form an organic-inorganic hardened layer. Thereby a cover window using PET as a substrate was manufactured.

<Evaluation>

The physical properties were measured by the following method, and the results are shown in Table 1 below.

1. Pressing Properties

An optical clear adhesive film (3M, thickness: 20 μm) as an adhesive layer and a glass substrate were sequentially laminated on one surface of the cover window of Examples and Comparative Examples using a lamination equipment at room temperature.

Then, a pencil was fixed at an angle of 45° under a load of 300 g to the cover window using a pencil hardness tester and then scratched by 20 mm for each pencil hardness 5 times in total, and it was judged whether it is scratched with the naked eye, and the maximum pencil hardness at which surface damage (cracks of 1 mm or more) did not occur more than three times was measured.

2. Dynamic Bending Properties

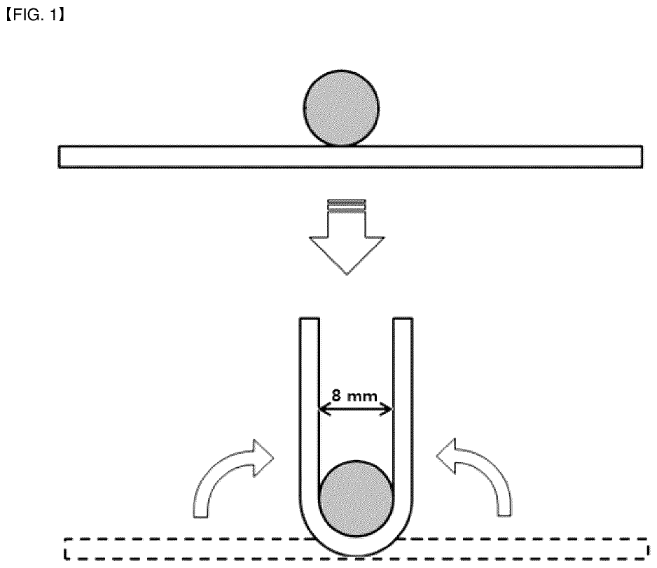

FIG. 1 schematically illustrates a method for evaluating dynamic bending properties for a cover window according to an embodiment of the present invention.

Specifically, the cover window was cut, but was laser cut into a size of 80×140 mm so as to minimize fine cracks in the edge portion. The laser-cut film was placed on the measuring device, and the distance (inner curvature diameter) of the folded portion was set to 8 mm. A continuous operation of folding and spreading both sides of the cover window at 90 degrees toward the bottom surface at room temperature was repeated 200,000 times (the speed at which the cover window was folded was once per second at 25° C.), and dynamic bending properties were evaluated according to the following <Evaluation Criteria>.

<Evaluation Criteria>
Excellent: No cracks of 1 mm or more occur
Defective: cracks of 1 mm or more occur

TABLE 1

| | | | | Comparative | Comparative | Comparative |
|---|---|---|---|---|---|---|
| | Example 1 | Example 2 | Example 3 | Example 1 | Example 2 | Example 3 |
| organic- | Preparation | Preparation | Preparation | Preparation | Comparative | Preparation |
| inorganic | Example 1 | Example 1 | Example 1 | Example 1 | Preparation | Example 1 |
| hardened | | | | | Example 1 | |
| layer | | | | | | |
| Coating | 60 | 100 | 200 | 300 | 100 | 10 |
| thickness (μm) | | | | | | |
| Pressing | 1H | 5H | 6H | 6H | 3B or less | 3B or less |
| properties | | | | | | |
| Dynamic | Excellent | Excellent | Excellent | Defective | Defective | Excellent |
| bending | | | | | | |
| properties | | | | | | |

According to Table 1, it was confirmed that the cover windows of Examples 1 to 3 have excellent dynamic bending properties while exhibiting pressing properties of 1H or more.

On the other hand, it was confirmed that Comparative Example 1 was defective in dynamic bending properties because the thickness of the cover window was too thick, Comparative Example 2 had defective compressive properties and insufficient flexibility of the hardened product, resulting in defective bending properties, and Comparative Example 3 formed a thin hardened layer by including the substrate, so that the pressing properties were significantly deteriorated.

1. A cover window of substrate-less type for a flexible display device type, comprising:
an organic-inorganic hardened layer including polysiloxane containing an epoxy group-containing functional group, wherein the cover window does not comprise a substrate.

2. The cover window of substrate-less type for a flexible display device according to claim 1, wherein:
the organic-inorganic hardened layer has a thickness of 50 μm or more and 700 μm or less.

3. The cover window of substrate-less type for a flexible display device according to claim 1, wherein:
the polysiloxane containing an epoxy group-containing functional group comprises two or more repeating units having different structures.

4. The cover window of substrate-less type for a flexible display device according to claim 3, wherein:
in the FT-IR spectrum measured by an attenuated total reflection (ATR) method for the polysiloxane containing two or more repeating units having different structures, the cover window has at least one peak in the region of 1010 cm⁻¹ to 1070 cm⁻¹, and at least one peak in the region of 1075 cm⁻¹ to 1130 cm⁻¹.

5. The cover window of substrate-less type for a flexible display device according to claim 4, wherein:
a peak intensity ratio (I₂/I₁) of an intensity (I₂) for the highest intense peak among at least one peak appearing in the region of 1075 cm⁻¹ to 1130 cm⁻¹ to an intensity (I₁) for the highest intense peak among at least one peak appearing in the region of 1010 cm⁻¹ to 1070 cm⁻¹ is 1.2 or more and 2.5 or less.

6. The cover window of substrate-less type for a flexible display device according to claim 1, wherein:
the polysiloxane containing an epoxy group-containing functional group contains 70 mol % or more of repeating units containing the epoxy group-containing functional group.

7. The cover window of substrate-less type for a flexible display device according to claim 1, wherein:
the organic-inorganic hardened layer contains 10 parts by weight or more and 80 parts by weight or less of an elastomeric polymer based on 100 parts by weight of the polysiloxane containing the epoxy group-containing functional group.

8. The cover window of substrate-less type for a flexible display device according to claim 7, wherein:
the elastomeric polymer comprises polycaprolactone polyol having a number average molecular weight (Mn) of 300 Da or more and 10,000 Da or less.

9. The cover window of substrate-less type for a flexible display device according to claim 1, wherein:
when the cover window is placed at an interval of 8 mm in the middle, and processes of folding and spreading the organic-inorganic hardened layer at a 90° angle to face each other are repeatedly performed 200,000 times at a rate of once per second at room temperature, a crack of 1 mm or more does not occur on organic-inorganic hardened layer of the cover window.

10. A display device comprising:
the cover window of substrate-less type for a flexible display device according to claim 1;
an adhesive layer formed on one surface of the cover window; and
a display panel formed on the adhesive layer.

11. A method for manufacturing a display device comprising:
a step of laminating a cover window of substrate-less type on one surface of a display panel,
wherein the cover window of substrate-less type is made of an organic-inorganic hardened layer including polysiloxane containing an epoxy group-containing functional group.

12. The method for manufacturing a display device according to claim 11, wherein:
the organic-inorganic hardened layer has a thickness of 50 μm or more and less than 300 μm.

13. The method for manufacturing a display device according to claim 11, wherein:
the polysiloxane containing an epoxy group-containing functional group comprises two or more repeating units having different structures.

14. The method for manufacturing a display device according to claim 13, wherein:
in the FT-IR spectrum measured by an attenuated total reflection (ATR) method for the polysiloxane containing two or more repeating units having different structures, the cover window has at least one peak in the region of 1010 cm⁻¹ to 1070 cm⁻¹, and at least one peak in the region of 1075 cm⁻¹ to 1130 cm⁻¹, and
a peak intensity ratio (I₂/I₁) of an intensity (I₂) for the highest intense peak among at least one peak appearing in the region of 1075 cm⁻¹ to 1130 cm⁻¹ to an intensity (I₁) for the highest intense peak among at least one peak appearing in the region of 1010 cm⁻¹ to 1070 cm⁻¹ is 1.2 or more and 2.5 or less.

15. The method for manufacturing a display device according to claim 11, wherein:
before the step of laminating a cover window of substrate-less type on one surface of a display panel, the method further comprises the steps of:
forming an organic-inorganic hardened layer including polysiloxane containing an epoxy group-containing functional group on one surface of a release film;
peeling the release film from the organic-inorganic hardened layer; and
forming an adhesive layer on one surface of the organic-inorganic hardened layer from which the release film has been peeled or on one surface of the display panel,
wherein the display panel and the cover window made of the organic-inorganic hardened layer are laminated via an adhesive layer interposed therebetween.

16. The method for manufacturing a display device according to claim 11 wherein:
before the step of laminating a cover window of substrate-less type on one surface of a display panel, the method further comprises the steps of:
preparing a release film where an adhesive layer is formed on one surface;
forming an organic-inorganic hardened layer including polysiloxane containing an epoxy group-containing functional group on the adhesive layer; and
peeling the release film,
wherein the display panel and the cover window made of the organic-inorganic hardened layer are laminated via an adhesive layer interposed therebetween.
